(19) United States
(12) Patent Application Publication
(10) Pub. No.: US 2025/0321490 A1
(43) Pub. Date: Oct. 16, 2025

(54) SUBSTRATE TREATMENT METHOD, SUBSTRATE TREATMENT APPARATUS, AND COMPUTER STORAGE MEDIUM

(71) Applicant: Tokyo Electron Limited, Tokyo (JP)

(72) Inventors: Yuichi TERASHITA, Koshi City (JP); Kosuke YOSHIHARA, Koshi City (JP); Yukinobu OTSUKA, Koshi City (JP); Teruhiko KODAMA, Koshi City (JP)

(21) Appl. No.: 19/169,426

(22) Filed: Apr. 3, 2025

(30) Foreign Application Priority Data
Apr. 12, 2024 (JP) 2024-064696

(51) Int. Cl. G03F 7/36; G03F 7/38

(52) U.S. Cl. CPC G03F 7/36; G03F 7/38

(57) ABSTRACT

A substrate treatment method includes developing a substrate on which a coating film of a metal-containing resist has been formed and which has been subjected to exposure processing and a heat treatment after the exposure processing, wherein the developing includes exposing the substrate to an acid atmosphere being an atmosphere containing at least any one of gas and mist of a weak acid, while heating the substrate.

### CROSS REFERENCE TO RELATED APPLICATIONS

This application is based upon and claims the benefit of priority of the prior Japanese Patent Application No. 2024-64696, filed in Japan on Apr. 12, 2024, the entire contents of which are incorporated herein by reference.

### TECHNICAL FIELD

This disclosure relates to a substrate treatment method, a substrate treatment apparatus, and a computer storage medium.

### BACKGROUND

Japanese Laid-open Patent Publication No. 2022-96081 discloses a developing method of performing a developing treatment on a substrate including supplying a developing solution containing an organic solvent to the substrate which has a metal-containing coating film exposed in a predetermined pattern.

### SUMMARY

An aspect of this disclosure is a substrate treatment method including developing a substrate on which a coating film of a metal-containing resist has been formed and which has been subjected to exposure processing and a heat treatment after the exposure processing, wherein the developing includes exposing the substrate to an acid atmosphere being an atmosphere containing at least any one of gas and mist of a weak acid, while heating the substrate.

### BRIEF DESCRIPTION OF THE DRAWINGS

FIG. 1 is a plan view schematically illustrating the outline of a configuration of a wafer treatment system as a substrate treatment apparatus according to an embodiment.

FIG. 2 is a front view schematically illustrating the outline of the configuration of the wafer treatment system as the substrate treatment apparatus according to the embodiment.

FIG. 3 is a longitudinal sectional view schematically illustrating the outline of a configuration of a developing unit.

FIG. 4 is a bottom view schematically illustrating the outline of a configuration of an upper chamber.

FIG. 5 is a flowchart illustrating main processes of Example 1 of a treatment sequence.

FIG. 6 is an explanatory view illustrating the operation of the developing unit in FIG. 3.

FIG. 7 is a chart illustrating the result at the time when performing development for forming a pillar pattern of a metal-containing resist.

FIG. 8 is a chart illustrating the result at the time when performing development for forming the pillar pattern of the metal-containing resist.

FIG. 9 is a chart illustrating the result at the time when performing development for forming the pillar pattern of the metal-containing resist.

FIG. 10 is a chart illustrating the result at the time of performing development for forming a line-and-space pattern of the metal-containing resist.

FIG. 11 is a chart illustrating the result at the time of performing development for forming the line-and-space pattern of the metal-containing resist.

FIG. 12 is a chart illustrating the result at the time of performing development for forming the line-and-space pattern of the metal-containing resist.

FIG. 13 is a chart illustrating the result of etching using the line-and-space pattern of the metal-containing resist as a mask.

### DETAILED DESCRIPTION

In photolithography in a manufacturing process of a semiconductor device or the like, a series of treatments is performed for forming a desired pattern of a resist on a substrate such as a semiconductor wafer (hereinafter, referred to as a “wafer”). The series of treatments includes, for example, a resist coating treatment of supplying a resist solution onto the substrate to form a coating film of the resist (hereinafter, a resist film), exposure processing of exposing the resist film in a predetermined pattern, a PEB (Post Exposure Bake) treatment of heating the substrate after the exposure in order to promote a chemical reaction in the exposed resist film, a developing treatment of developing the substrate after the exposure processing to form a pattern of a resist, and so on.

In the above developing treatment, for example, a developing solution is supplied onto the substrate to form a liquid film of the developing solution on the substrate surface, whereby the substrate is developed. Further, in some cases, a cleaning solution such as pure water is then supplied onto the substrate, and the substrate is rotated at high speed and thereby cleaned.

Incidentally, in recent years, advances in exposure technology and the like have further miniaturized the semiconductor device, namely, miniaturized the resist pattern. In a fine resist pattern, if the developing solution or the cleaning solution remains on the substrate in the above-explained developing treatment, problems may arise. For example, when the developing solution or the cleaning solution remains between patterns, the remaining developing solution or cleaning solution may cause so-called pattern collapse due to its surface tension.

Further, conventionally, a chemically amplified resist is often used as the resist, but a non-chemically amplified metal-containing resist is sometimes used in recent years. This metal-containing resist is expected as a resist more suitable in the case of forming a fine pattern. However, even in the case of using the metal-containing resist, collapse of the pattern, namely, pattern collapse being a type of defect may occur if it is tried to develop the substrate using a treatment solution such as the developing solution to form a fine resist pattern.

Hence, the technique according to this disclosure suppresses the occurrence of a defect such as pattern collapse to obtain an excellent pattern of a metal-containing resist.

Hereinafter, a substrate treatment method and a substrate treatment apparatus according to this embodiment will be explained with reference to the drawings. Note that, in this description and the drawings, the same codes denote components having substantially the same functional configurations to omit duplicate explanations.

### Wafer Treatment System

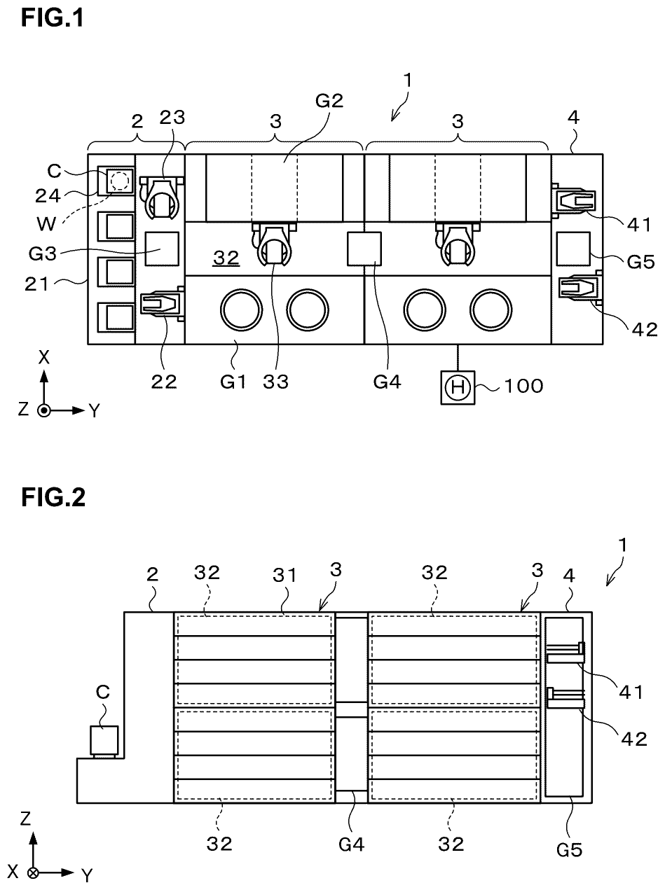

First, the configuration of a wafer treatment system as a substrate treatment system according to this embodiment will be explained. FIG. 1 and FIG. 2 are a plan view and a front view schematically illustrating the outline of a configuration of a wafer treatment system 1, respectively. In this embodiment, a case where the wafer treatment system 1 is a photolithography processing system which performs a forming treatment and a developing treatment of the resist film on the wafer W will be explained as an example.

The wafer treatment system 1 has a cassette station 2 into/out of which a cassette C housing a plurality of wafers W is transferred and a treatment station 3 including a plurality of various treatment apparatuses which perform predetermined treatments on the wafer Was illustrated in FIG. 1. The wafer treatment system 1 has a configuration in which the cassette station 2, the treatment station 3, and an interface station 4 which delivers the wafer W to/from an exposure apparatus (not illustrated) adjacent to a side opposite to the treatment station 3 are integrally connected. Note that two treatment stations 3 are installed between the cassette station 2 and the interface station 4 as illustrated in FIG. 1, but one or three treatment stations 3 may be installed.

In the cassette station 2, a cassette stage 21, a wafer transfer apparatus 22, and a wafer transfer apparatus 23 are provided. On the cassette stage 21, a plurality of cassette stage plates 24 are arranged side by side in an X-direction. In the cassette station 2, the wafer transfer apparatus 22 or the wafer transfer apparatus 23 transfers the wafer between the cassette C mounted on the cassette stage 21 and the treatment station 3. Therefore, each of the wafer transfer apparatus 22 and the wafer transfer apparatus 23 is provided with a drive mechanism for moving in each of directions such as horizontal directions (X-direction and Y-direction) and an up-down direction (Z-direction) and around a vertical axis (in a θ-direction) as necessary, and may be provided with a drive mechanism for moving in all directions.

At least any of the wafer transfer apparatus 22 and the wafer transfer apparatus 23 can deliver the cassette C and the wafer W, and can perform a delivery operation of the wafer to/from the treatment station 3. Note that the delivery operation of the wafer W to/from the treatment station 3 means, for example, delivery of the wafer to/from a third block G3 including a delivery apparatus accessible by a later-explained wafer transfer apparatus 33 in the treatment station 3. The third block G3 may include a plurality of delivery apparatuses (not illustrated) lined up in the up-down direction.

Note that an inspection apparatus (not illustrated) which performs inspection on the wafer W may be provided at a position accessible by any of the wafer transfer apparatus 22 and the wafer transfer apparatus 23.

In the treatment station 3, a plurality of blocks, for example, first, second, and fourth three blocks G1, G2, G4 are provided. Further, as illustrated in FIG. 2, a plurality of layers 31 including the first and second blocks G1, G2 are stacked in the up-down direction. For example, the first block G1 is provided on the front side (X-direction negative direction side in FIG. 1) in the treatment station 3, and the second block G2 is provided on the rear side (X-direction positive direction side in FIG. 1) in the treatment station 3. The fourth block G4 is provided on the interface station 4 side (Y-direction positive direction side in FIG. 1) in the treatment station 3 or at a connection portion with adjacent another treatment station 3. The fourth block G4 may include a plurality of delivery apparatuses lined up in the up-down direction. Besides, the above third block G3 may be provided in the treatment station 3.

In the first block G1, a plurality of treatment apparatuses, for example, a patterning film forming apparatus and a developing treatment apparatus which are not illustrated are arranged. As the patterning film forming apparatus, for example, an anti-reflection film forming apparatus can be included in addition to the resist film forming apparatus.

For example, the plurality of treatment apparatuses are arranged side by side in the horizontal direction in the first block G1. Note that the numbers, arrangements, and types of the treatment apparatuses in the first block G1 can be arbitrarily selected.

In the patterning film forming apparatus and the developing treatment apparatus, predetermined treatments are performed, for example, by supplying predetermined treatment solutions or supplying predetermined gases onto the wafer W. In this manner, the formation of a resist film to be used as a mask when forming a pattern of a film on the lower layer side or the formation of an anti-reflection film for efficiently performing light irradiation processing as an example of exposure processing is performed in the patterning film forming apparatus. On the other hand, a concave and convex shape as the above mask is formed by removing a part of the exposed resist film in the developing treatment apparatus.

For example, in the second block G2, thermal treatment apparatuses (not illustrated) which perform thermal treatments such as heating and cooling of the wafer W are provided side by side in the up-down direction and the horizontal direction. Further, in the second block G2, not-illustrated hydrophobization treatment apparatuses which perform a hydrophobization treatment in order to enhance the fixation between the resist solution and the wafer W and not-illustrated edge exposure apparatuses which expose an outer peripheral portion of the wafer W are provided side by side in the up-down direction (Z-direction) and the horizontal direction. The numbers and arrangements of the thermal treatment apparatuses, the hydrophobization treatment apparatuses, and the edge exposure apparatuses can also be arbitrarily selected.

As illustrated in FIG. 1, in a region sandwiched between the first block G1 and the second block G2 in plan view, a wafer transfer region 32 is formed. In the wafer transfer region 32, for example, the wafer transfer apparatus 33 is arranged.

The wafer transfer apparatus 33 has a transfer arm movable, for example, in the Y-direction, the front-rear direction, the θ-direction, and the Z-direction. The wafer transfer apparatus 33 can move in the wafer transfer region 32 to transfer the wafer W to predetermined apparatuses in the first block G1, the second block G2, the third block G3, and the fourth block G4 therearound. In the case where the plurality of treatment stations 3 exist as in FIG. 1, the wafer transfer apparatus 33 provided in the treatment station 3 located on the interface station 4 side can transfer the wafer W to predetermined apparatuses in a later-explained fifth block G5 in addition to the first, second, and fourth blocks G1, G2, G4.

A plurality of the wafer transfer apparatuses 33 are provided, for example, one above the other. One wafer transfer apparatus 33 can transfer the wafer W to predetermined apparatuses located at heights of the plurality of layers 31 on the upper side of the plurality of layers 31 stacked one on top of the other. The other wafer transfer apparatus 33 can transfer the wafer W to predetermined apparatuses located at heights of the plurality of layers 31 located below the layers 31 on the upper side. A plurality of the wafer transfer regions 32 are provided so as to enable the transfer of the wafer W. Note that the number of the wafer transfer apparatuses 33 and the number of the layers 31 corresponding to one wafer transfer apparatus 33 can be arbitrarily selected such that the wafer transfer apparatus 33 is provided for each layer 31.

Further, in the wafer transfer region 32 or the first block G1 or the second block G2, a shuttle transfer apparatus (not illustrated) may exist. The shuttle transfer apparatus linearly transfers the wafer W between a space adjacent to one of the treatment stations 3 and another space adjacent to the side opposite thereto.

In the interface station 4, the fifth block G5 including a plurality of delivery apparatuses, a wafer transfer apparatus 41, and a wafer transfer apparatus 42 are provided. The interface station 4 transfers the wafer W using the wafer transfer apparatus 41 or the wafer transfer apparatus 42 between the fifth block G5 to/from which the wafer W is delivered by the wafer transfer apparatus 33 and an exposure apparatus. Therefore, the wafer transfer apparatus 41 and the wafer transfer apparatus 42 each have a drive mechanism for moving in each of directions such as the X-direction, the Y-direction, the Z-direction, and around a vertical axis (in the θ-direction) as necessary, and may include a drive mechanism for moving in all directions. At least any of the wafer transfer apparatus 41 and the wafer transfer apparatus 42 can support the wafer W and transfer the wafer W between the delivery apparatus in the fifth block G5 and the exposure apparatus.

A cleaning apparatus which cleans the surface of the wafer W and the above edge exposure apparatus may be provided at positions accessible by any of the wafer transfer apparatus 41 and the wafer transfer apparatus 42 in the interface station 4.

The inspection apparatus may be provided in the cassette station 2 as explained above, but may be provided at a position accessible by any of the wafer transfer apparatuses 33, 41, 42 provided in the treatment station 3 and the interface station 4, respectively.

In the above wafer treatment system 1, at least one controller 100 is provided as illustrated in FIG. 1. The controller 100 processes computer-readable instructions causing the wafer treatment system 1 to execute various processes explained in this disclosure. The controller 100 can be configured to control components in the wafer treatment system 1 so as to execute the various processes explained herein. In one embodiment, part or whole of the controller 100 may be included in the wafer treatment system 1. The controller 100 may include a processor, a storage, and a communication interface. The controller 100 is implemented, for example, by a computer. The processor can be configured to read from the storage a program which provides a logic or routine enabling performance of various control operations and execute the read program to thereby perform the various control operations. This program may be stored in the storage in advance, or acquired via a medium when required. The acquired program is stored in the storage, and read out of the storage and executed by the processor. The medium may be various computer-readable storage media or may be a communication line connected to the communication interface. The storage medium may be a transitory one or a non-transitory one. The processor may be a CPU (Central Processing Unit), or may be one or a plurality of circuits. The storage may include a RAM (Random Access Memory), a ROM (Read Only Memory), an HDD (Hard Disk Drive), an SSD (Solid State Drive), or a combination of them. The communication interface may communicate with the wafer treatment system 1 via a communication line such as a LAN (Local Area Network).

Note that the wafer treatment system in this disclosure is not limited to the above-explained configuration. For example, the wafer treatment system is directly connected to the exposure apparatus and delivers the wafer W between the interface station 4 and the exposure apparatus in the above embodiment, but the wafer treatment system does not need to be directly connected to the exposure apparatus. In this case, for example, the wafer W is transferred from the cassette station 2 to the treatment station 3 and subjected to required treatments and then transferred again to the cassette station 2 to be transferred to the outside of the system.

Further, the one among the listed treatment apparatuses that is not required does not need to be provided in the wafer treatment system, or the treatment in that apparatus does not need to be performed.

### Type of the Resist

In the wafer treatment system 1 in this disclosure, the coating film of the resist to be formed on the wafer W by the resist film forming apparatus, namely, a resist film is a coating film of a metal-containing resist, namely, a metal-containing resist film.

Besides, the metal contained in the metal-containing resist is optional and is, for example, tin. Note that the metal-containing resist used in the wafer treatment system 1 is negative type.

### Developing Unit 200

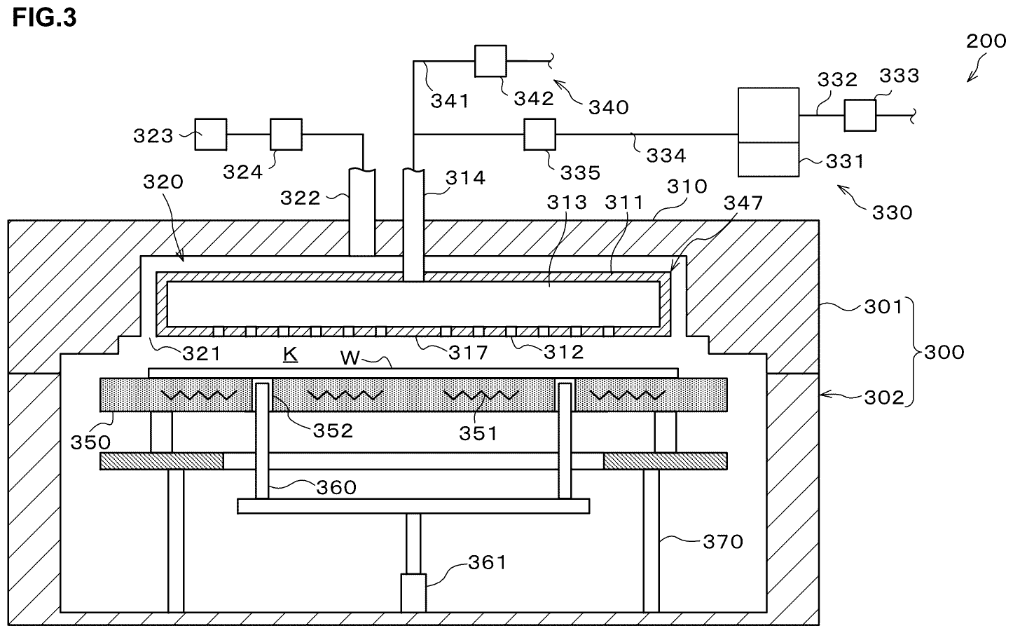

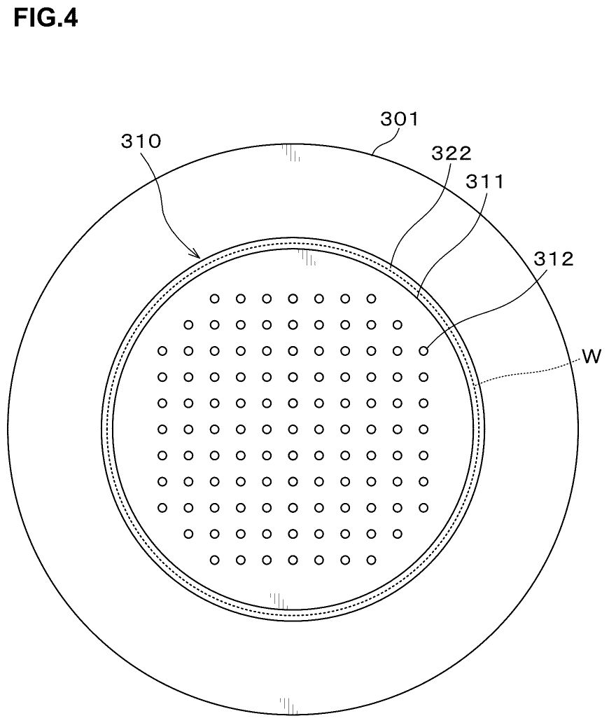

Next, the developing unit 200 will be explained. FIG. 3 is a longitudinal sectional view schematically illustrating the outline of a configuration of the developing unit 200. FIG. 4 is a bottom view schematically illustrating the outline of a configuration of a later-explained upper chamber 301.

The developing unit 200 in FIG. 3 is provided with a chamber 300 which covers a treatment space K on a later-explained hot plate 350 and houses the wafer W during a thermal treatment. The chamber 300 has an upper chamber 301 located on the upper side, and a lower chamber 302 located on the lower side and capable of closing the inside together with the upper chamber 301.

The upper chamber 301 is configured to be freely raised and lowered by a raising and lowering mechanism (not illustrated). The raising and lowering mechanism has a driving source (not illustrated) such as a motor which generates a driving force for raising and lowering the upper chamber 301. The raising and lowering mechanism is controlled by the controller 100.

Further, the upper chamber 301 is formed, for example, in an almost cylindrical shape with the lower surface open. The upper chamber 301 has a ceiling part 310. The ceiling part 310 forms the treatment space K therebelow, and is provided in a manner to face the wafer W on the later-explained hot plate 350. Further, the ceiling part 310 is provided with a shower head 311 as a gas discharger.

The shower head 311 discharges a treatment gas containing gas of a weak acid into the chamber 300. Specifically, the treatment gas containing the gas of the weak acid is discharged from the ceiling part 310 toward the hot plate 350. The gas of the weak acid is, for example, gas of a carboxylic acid being a weak acid. The gas of the carboxylic acid being the weak acid may be, for example, vapor of acetic acid. The “weak acid” in this disclosure indicates the strength of acid at which the development of the metal-containing resist does not proceed at room temperature (20° C. to 30° C.) and specifically means acid having a value of an acid dissociation constant (pka) of 4 or more (for example, about 5). Further, the treatment gas containing the gas of the weak acid may contain gas of an organic solvent. The treatment gas containing the gas of the weak acid contains, for example, a vaporized substance, namely, vapor of a mixed solution of the carboxylic acid being the weak acid and the organic solvent and a carrier gas. Besides, the treatment gas containing the gas of the weak acid may be the one containing a vaporized substance from the carboxylic acid being the weak acid alone and a carrier gas. The carboxylic acid being the weak acid is specifically, for example, acetic acid. The organic solvent is, for example, propylene glycol monomethyl ether acetate (PGMEA). The carrier gas is, for example, an inert gas such as a nitrogen gas or an argon (Ar) gas.

In this embodiment, the shower head 311 discharges also an inert gas such as a nitrogen gas or an Ar gas into the chamber 300. In other words, the shower head 311 functions also as another gas discharger which discharges the inert gas into the chamber 300.

Further, the shower head 311 has a plurality of discharge holes 312 and a gas distribution space 313.

Each of the discharge holes 312 is formed at a lower surface of the shower head 311. The discharge holes 312 are arranged almost uniformly at a central portion of the lower surface of the shower head 311 as illustrated, for example, in FIG. 4.

The gas distribution space 313 distributes the gas introduced into the shower head 311 and supplies it to the discharge holes 312. As illustrated in FIG. 3, supply mechanisms 330, 340 are connected to the shower head 311 via a supply pipe 314.

The supply mechanism 330 supplies the treatment gas containing the gas of the weak acid to the shower head 311 (specifically, the gas distribution space 313). Further, the supply mechanism 330 has, for example, a tank 331 which stores the mixed solution of the carboxylic acid being the weak acid and the organic solvent as a raw material of the gas of the weak acid, and a supply pipe 332 which supplies the carrier gas to the tank 331. The tank 331 may be provided with a heater (not illustrated) which heats the mixed solution in order to promote the vaporization of the mixed solution. Further, the carrier gas may be used for bubbling of the mixed solution in the tank 331 to vaporize the mixed solution. The supply pipe 332 is provided with a supply equipment group 333 including an opening/closing valve, a flow regulating valve, and so on for controlling the flow of the carrier gas.

Further, the supply mechanism 330 has an introduction pipe 334 which introduces the treatment gas containing the gas of the weak acid from the shower head 331 into the supply pipe 314. The introduction pipe 334 is provided with a supply equipment group 335 including an opening/closing valve, a flow regulating valve, and so on for controlling the flow of the treatment gas containing the gas of the weak acid.

The supply equipment groups 333, 335 are controlled by the controller 100.

The supply mechanism 340 has an introduction pipe 341 which introduces the inert gas stored in a storage source (not illustrated) into the supply pipe 314. The introduction pipe 341 is provided with a supply equipment group 342 including an opening/closing valve, a flow regulating valve, and so on for controlling the flow of the inert gas.

The supply equipment group 342 is controlled by the controller 100.

Further, the ceiling part 310 of the upper chamber 301 is provided with a peripheral exhauster 320. The peripheral exhauster 320 exhausts the treatment space K from above a peripheral edge portion of the wafer W on the hot plate 350 in the ceiling part 310. The peripheral exhauster 320 has an exhaust port 321. The exhaust port 321 opens downward from the lower surface of the ceiling part 310 in a manner to surround the outer periphery of the shower head 311 as illustrated in FIG. 4. The exhaust port 321 may be composed of a plurality of exhaust holes lined up along the outer periphery of the shower head 311. The peripheral exhauster 320 exhausts the treatment space K via the exhaust port 321. The peripheral exhauster 320 constitutes an exhauster which exhausts the chamber 300, namely, the treatment space K.

The exhaust port 321 is provided, for example, between a position where a peripheral edge of the exhaust port 321 overlaps with a peripheral edge of the wafer W on the hot plate 350 and a position 10 mm inside of the former position in top view.

The peripheral exhauster 320 in FIG. 3 has a peripheral exhaust path extending from the exhaust port 321. To the peripheral exhaust path, an exhaust apparatus 323 such as a vacuum pump is connected via an exhaust pipe 322. The exhaust pipe 322 is provided with an exhaust equipment group 324 having a valve and so on which regulate the exhaust rate. The exhaust apparatus 323 and the exhaust equipment group 324 are controlled by the controller 100.

Further, a central exhauster may be provided which exhausts the treatment space K from above the central portion of the wafer W on the hot plate 350. In this case, exhaust from the central exhauster may be performed at predetermined timing in a thermal treatment process period. An exhaust path of the central exhauster may be provided, for example, from the upper surface of the ceiling part 310 to the lower surface side of the shower head 311 in a manner to penetrate a central region of the shower head 311. On the lower surface side of the shower head 311, one or a plurality of exhaust ports of the central exhauster may be provided.

The lower chamber 302 is provided, for example, in a manner to surround the periphery of the hot plate 350 (specifically, the lateral side and the lower side of the hot plate 350).

The hot plate 350 is for heating the wafer W. Further, the hot plate 350 is configured to be able to support the wafer W. The hot plate 350 has a thick disk shape. The hot plate 350 has, for example, a heater 351 built therein. The heater 351 is, for example, a resistance heating heater. The temperature of the hot plate 350 is regulated by the control of the heater 351 by the controller 100 and thus, for example, the wafer W mounted on the hot plate 350 is heated to a predetermined temperature.

Further, the hot plate 350 is provided with a plurality of suction holes (not illustrated) for sucking the wafer W to the hot plate 350.

The hot plate 350 may be configured to able to heat the wafer W so that the temperature of the wafer W differs in a radial direction of the wafer W.

Further, in the lower chamber 302, for example, three raising and lowering pins 360 which support the wafer W from below and raise and lower the wafer W are provided below the hot plate 350. The raising and lowering pins 360 are raised and lowered by a raising and lowering mechanism 361. The raising and lowering mechanism 361 has a driving source (not illustrated) such as a motor which generates a driving force for raising and lowering the raising and lowering pins 360. The raising and lowering mechanism 361 is controlled by the controller 100. At the central portion of the hot plate 350, through holes 352 are formed through which the raising and lowering pins 360 pass. The raising and lowering pins 360 can pass through the through holes 352 and project from the upper surface of the hot plate 350.

The hot plate 350 is supported, for example, on a bottom wall of the lower chamber 302. Specifically, the hot plate 350 is supported on the bottom wall of the lower chamber 302, for example, via a support 370.

Note that in the example explained using FIG. 1 and FIG. 2, the developing treatment apparatus is provided in the first block G1 in the wafer treatment system 1. In contrast to the above, regarding the developing unit 200, for example, it is provided in the second block G2, where a thermal treatment apparatus having a hot plate and so on as in the developing unit 200 is located.

### Example 1 of a Treatment Sequence

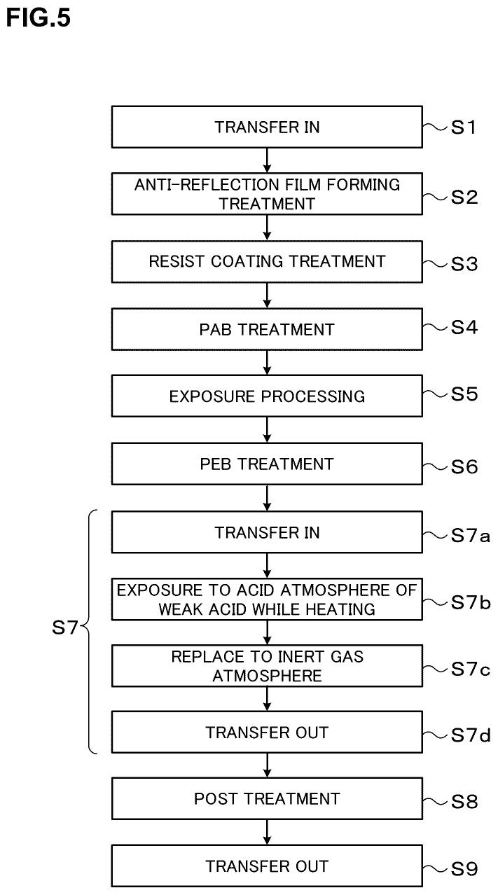

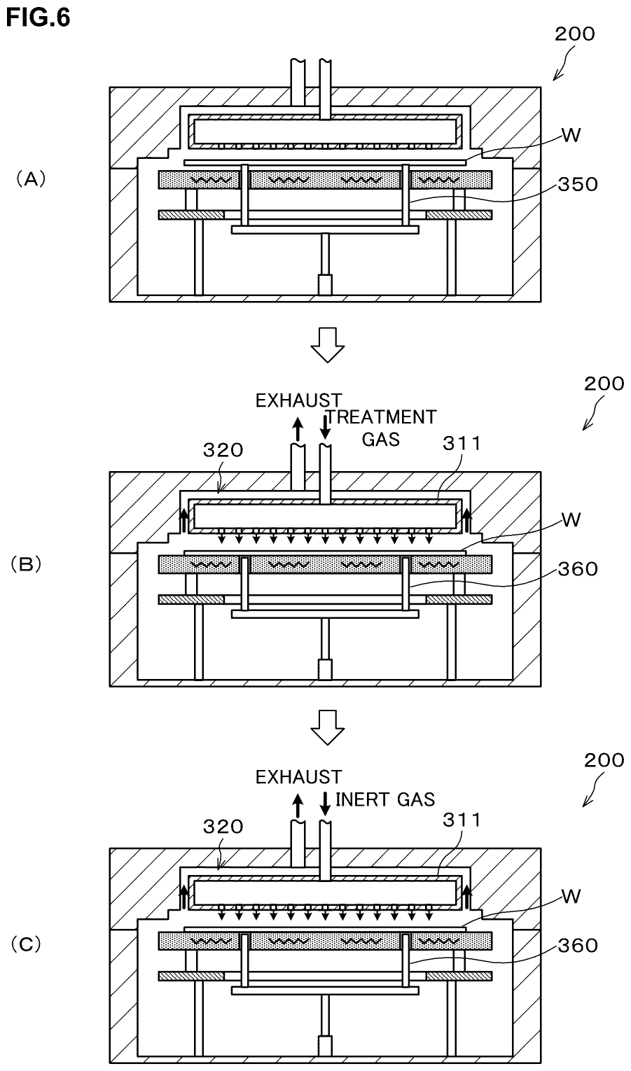

Next, an example of a treatment sequence executed by the wafer treatment system 1 will be explained. FIG. 5 is a flowchart illustrating main processes of Example 1 of a treatment sequence. FIG. 6 is an explanatory view illustrating the operation of the developing unit 200.

### Step S1

First, the wafer W is transferred into the wafer treatment system 1.

Specifically, the cassette C housing a plurality of wafers W is transferred into the cassette station 2 of the wafer treatment system 1 and mounted on the cassette stage plate 24. Then, the wafers W in the cassette C are successively taken out by the wafer transfer apparatus 22 or the wafer transfer apparatus 23, and transferred to the delivery apparatus in the third block G3.

### Step S2

Next, the anti-reflection film forming treatment is performed on the wafer W to form an anti-reflection film on the wafer W.

Specifically, the wafer W transferred to the delivery apparatus in the third block G3 is supported by the wafer transfer apparatus 33 and transferred to the anti-reflection film forming apparatus provided in the first block G1, in which an anti-reflection film is formed as a base film for the metal-containing resist in a manner to cover the surface of the wafer W. This Step S2 may be omitted.

### Step S3

Next, the resist coating treatment is performed on the wafer W to form a metal-containing resist film on the wafer W.

Specifically, the wafer W is supported by the wafer transfer apparatus 33 and transferred to the resist film forming apparatus provided in the first block G1, in which a negative metal-containing resist film is formed in a manner to cover the anti-reflection film as the base film on the wafer W.

### Step S4

Subsequently, the PAB treatment is performed on the wafer W.

Specifically, the wafer W is supported by the wafer transfer apparatus 33 and transferred to the thermal treatment apparatus for the PAB treatment in the second block G2 and subjected to the PAB treatment. The wafer W is then transferred to the delivery apparatus in the fifth block G5. Note that the plurality of treatment stations 3 exist as in FIG. 1 and FIG. 2, the wafer W is placed once in the delivery apparatus in the fourth block G4 before the wafer W is transferred to the delivery apparatus in the fifth block G5, and then the wafer W is delivered between the plurality of wafer transfer apparatuses 33.

### Step S5

Next, the exposure processing is performed on the wafer W.

Specifically, the wafer W transferred to the delivery apparatus in the fifth block G5 is transferred by the wafer transfer apparatus 41 and the wafer transfer apparatus 42 to the exposure apparatus, and subjected to exposure processing in a predetermined pattern. The wafer W subjected to the exposure processing is transferred by the wafer transfer apparatus 41 and the wafer transfer apparatus 42 to the delivery apparatus in the fifth block G5.

### Step S6

Next, the PEB treatment is performed on the wafer W.

Specifically, the wafer W transferred to the delivery apparatus in the fifth block G5 after the exposure processing is transferred by the wafer transfer apparatus 33 to the thermal treatment apparatus for the PEB treatment and subjected to the PEB treatment.

### Step S7

Subsequently, the wafer W is developed (Step S7).

Specifically, following Steps S7a to S7d are performed.

### Step S7a

First, the wafer W is transferred into the chamber 300.

Specifically, the wafer W is first moved by the wafer transfer apparatus 33 into the developing unit 200, and then the raising and lowering pins 360 are raised and the transfer arm of the wafer transfer apparatus 33 is pulled out, whereby the wafer W is supported by the raising and lowering pins 360. Thereafter, the upper chamber 301 is lowered, so that the upper chamber 301 and the lower chamber 302 demarcate the treatment space K. In this event, the wafer W is, for example, continuously in a state of being supported by the raising and lowering pins 360 and separated from the hot plate 350 as illustrated in FIG. 6(A). Thereafter, the raising and lowering pins 360 supporting the wafer W are lowered to deliver and mount the wafer W to and on the hot plate 350. Further, the wafer W is sucked to the hot plate 350 via the suction holes (not illustrated).

### Step S7b

Next, the wafer W is exposed to an acid atmosphere being an atmosphere containing gases of a weak acid and an organic solvent, while being heated.

Specifically, as illustrated in FIG. 6(B), the discharge of the treatment gas containing the gases of the weak acid and the organic solvent from the shower head 311 toward the wafer W and the exhaust by the peripheral exhauster 320 are performed. Thus, the wafer W is exposed to the acid atmosphere containing the gas of the weak acid in the treatment space K, while being heated, and specifically exposed to the acid atmosphere containing the gas of the weak acid under a predetermined pressure at the atmospheric pressure or higher, while being heated. When the negative metal-containing resist film on the wafer W is exposed to the acid atmosphere, an unexposed portion reacts with the gas of the weak acid and lowers in molecular weight. Further, the unexposed portion which has lowered in molecular weight by the reaction with the gas of the weak acid of the negative metal-containing resist film on the wafer W sublimes by the heating of the wafer W, whereby a pattern of the metal-containing resist is formed. For example, in the case where the gas of the weak acid is gas of acetic acid and the metal-containing resist film contains tin as a metal, tin acetate sublimes.

Note that the “atmospheric pressure” is, for example, 670 Torr to 760 Torr.

Besides, the temperature of the wafer W at Step S7b is, for example, the same as that during the PEB treatment, specifically 100° C. to 200° C. This Step S7b is completed, for example, after a lapse of a predetermined time from when the supply of the treatment gas is started.

### Step S7c

On the other hand, in this process, the atmosphere around the wafer W is replaced from the acid atmosphere to an atmosphere of an inert gas.

Specifically, for example, as illustrated in FIG. 6(C), the supply of the inert gas is performed from the shower head 311 in the state where the exhaust by the peripheral exhauster 320 is continued without the wafer W being transferred to the outside of the chamber 300. This brings the inside of the chamber 300 from the acid atmosphere to an inert gas atmosphere. This Step S7c is completed by stop of the supply of the inert gas, for example, after a lapse of a predetermined time from when the supply of the inert gas is started.

### Step S7d

Thereafter, the wafer W is transferred out of the chamber 300.

Specifically, the wafer W is ejected from the chamber 300 and transferred to the outside of the developing unit 200, for example, in a procedure reverse to that at Step S7a.

Note that the treatment conditions of the development can be adjusted according to the dimension of the pattern.

### Step S8

After the development, a POST treatment is performed on the wafer W.

Specifically, the wafer W is transferred by the wafer transfer apparatus 33 to a thermal treatment unit 40 for the POST treatment and subjected to the POST treatment. This Step S8 may be omitted.

### Step S9

Then, the wafer W is transferred out of the wafer treatment system 1.

Specifically, the wafer W is transferred by the wafer transfer apparatus 33 to the delivery apparatus in the third block G3, and transferred by the wafer transfer apparatus 22 or 23 in the cassette station 2 to the cassette C on the predetermined cassette stage plate 24. This completes the series of photolithography processes.

### Main Operations and Effects of Example 1 of the Treatment Sequence

As explained above, in this example, the process of developing the wafer W which has the metal-containing resist film formed thereon includes the process of exposing the wafer W which has been subjected to the PEB treatment to the acid atmosphere containing the gas of the weak acid (specifically, the gases of the weak acid and the organic solvent), while heating wafer W. In other words, in this example, a portion to be removed by the development of the metal-containing resist film is removed by the gas of acetic acid and heat without using the treatment of the developing solution, cleaning solution, or the like to form the pattern of the metal-containing resist. Therefore, the pattern collapse due to the surface tension of the treatment solution never occurs. Therefore, according to this example, it is possible to suppress the pattern collapse of the metal-containing resist and thereby obtain an excellent pattern of the metal-containing resist.

Further, in this example, since the treatment gas containing the gas of the weak acid is used, it is possible to suppress the damage to the constituent members of the developing unit 200 such as the inner wall and the like of the chamber 300 by the treatment gas as compared with the case of using a treatment gas containing gas of a strong acid.

Further, in this example, the weak acid in the acid atmosphere has the strength of acid at which the development of the metal-containing resist does not proceed at room temperature. Therefore, in the state where the temperature of the wafer W is room temperature after the development process at Step S7 in Example 1 of the treatment sequence explained above, the development does not proceed and a metal-containing component (specifically, tin acetate or the like) being a reaction product at the development is less likely to be generated. Therefore, it is possible to suppress, after the development process at Step S7 in Example 1 of the treatment sequence explained above, the contamination of the surroundings of the wafer W after the development (for example, other wafers W and the like located above in the wafer treatment system 1 and in the cassette C) by the above metal-containing component.

Note that one conceivable reason why the weak acid can have the strength of acid at which the development of the metal-containing resist does not proceed at room temperature is that the development includes an acid-base reaction in which acid cuts the bonding. With the weak acid, the development is weak due to the inclusion of the acid-base reaction, and it is considered that the development is less likely to proceed unless heat is applied.

Further, after the above treatment sequence, the wafer W is subjected to etching using the pattern of the metal-containing resist as a mask, and it is possible to suppress the contamination of the surroundings of the wafer W after the development with the metal-containing component until the etching.

### Requirements in the Case Where the Developing Gas Contains Vapors (Gasses) of Acetic Acid and Organic Solvent

### 1. Requirements of a Spontaneous Ignition Point

The development by the mixed gas of acetic acid and organic solvent cannot be performed in terms of safety under the condition that the temperature in the treatment space K1, namely, the treatment temperature exceeds a spontaneous ignition temperature of the acetic acid or the organic solvent. Besides, the spontaneous ignition temperature of the organic solvent is generally lower than the spontaneous ignition temperature (485° C.) of acetic acid. For example, the spontaneous ignition temperature of PGMEA is 272° C. Therefore, the treatment temperature at the development by the mixed gas of the acetic acid and the organic solvent is limited to the spontaneous ignition temperature of the organic solvent. Accordingly, in the case where the treatment temperature at the development by the mixed gas of the acetic acid and the organic solvent is preferable in terms of the developing performance, an organic solvent high in spontaneous ignition temperature and close to that of acetic acid is preferable.

### 2. Requirements of Ease of Vaporization

In the case of vaporizing the mixed solution of acetic acid and organic solvent in the vaporizer to produce the mixed gas of the acetic acid and the organic solvent as the developing gas, if the acetic acid and the organic solvent are different in ease of vaporization, the concentration of the mixed solution in the vaporizer changes, resulting in that the acetic acid gas concentration in the developing gas to be produced also changes. This makes it difficult to keep constant the acetic acid gas concentration in the developing gas to be supplied to the treatment space K. Therefore, the acetic acid and the organic solvent are preferably close in ease of vaporization. Examples of a related parameter of the ease of vaporization of liquid include a boiling point and a vapor pressure. Liquid is less likely to vaporize as the boiling point is higher, and is more likely to vaporize as the boiling point is lower. Besides, liquid is more likely to vaporize as the vapor pressure is higher, and is less likely to vaporize as the vapor pressure is lower. Besides, in the case of mixed fluid, its ease of vaporization is in proportion to its mole fraction, and the mole fraction is decided from its molecular weight. In other words, the molecular weight is also a related parameter of the ease of vaporization.

Because of the above two requirements, in the case of producing the mixed gas from the mixed solution of the acetic acid and the organic solvent, it is preferable to use an organic solvent satisfying at least any one of the following (A) and (B).
(A) The spontaneous ignition temperature is equal to that of PGMEA generally used for the substrate treatment or closer to that of the acetic acid than that of PGMEA.
(B) At least any one of the boiling point under the same treatment pressure, the vapor pressure under the same treatment temperature, and the molecular weight is equal to that of PGMEA or closer to that of acetic acid than that of PGMEA.

There can be many such organic solvents, and some examples thereof include propylene glycol monomethyl ether (PGME), methyl isobutyl carbinol (MIBC), methyl isobutyl ketone (MIBK), butyl acetate (nBA), and γ-butyrolactone in addition to PGMEA. Further, an organic solvent meeting the above requirements among sulfoxides, sulfones, lactams, polyhydric alcohols, dialkyl glycol ethers, alkylene glycol monoalkyl ethers, alkylene glycol esters, alkylene glycol monoalkyl ether acetates, ketones, alkyl lactate esters, other ethers and esters, aliphatic hydrocarbons, aromatic hydrocarbons, and terpenes, may be used.

### Development Results

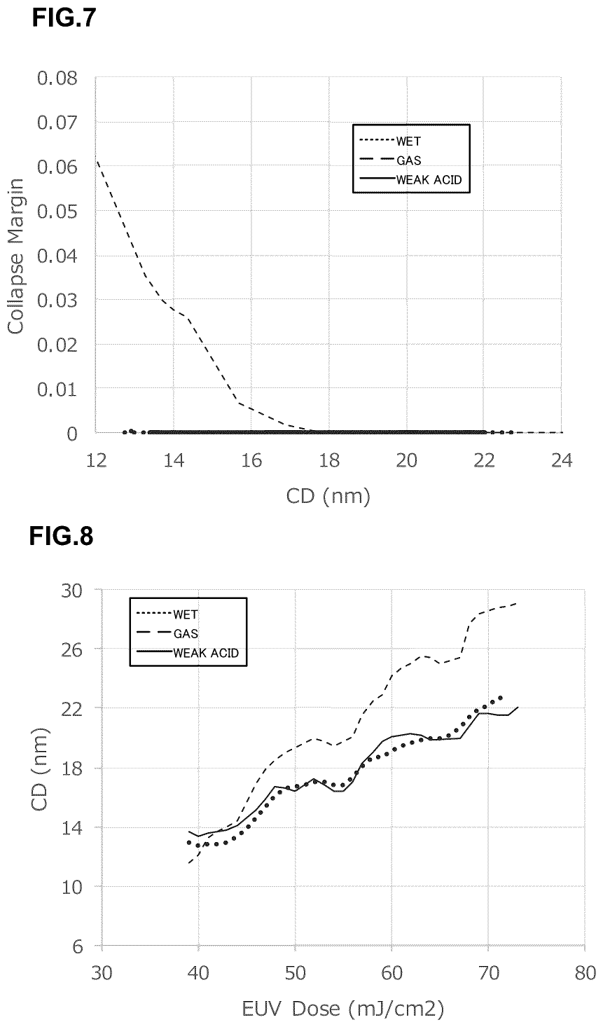

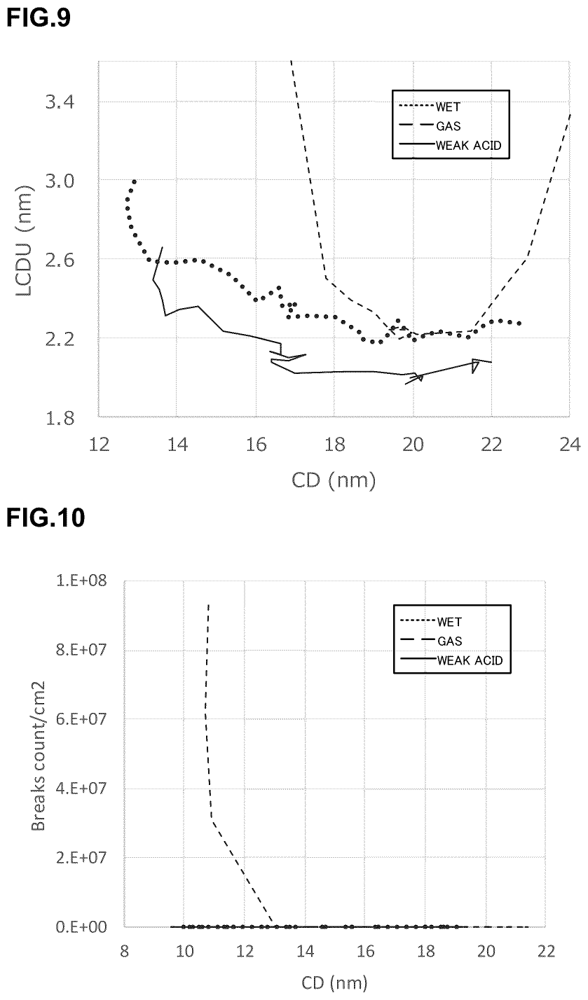

FIG. 7 to FIG. 9 are charts each illustrating the result at the time when performing development for forming a pillar pattern of the metal-containing resist, FIG. 7 illustrates a relation between a CD (Critical Dimension), namely, a diameter of a pillar and an occurrence rate of defects, FIG. 8 illustrates a relation between an exposure amount and the CD, namely, an exposure sensitivity, and FIG. 9 illustrates a relation between the CD and an LCDU (Local CD Uniformity). Note that the defects whose occurrence rate is illustrated in FIG. 7 is caused by pattern collapse. Besides, the LCDU in FIG. 9 is a variation (2σ) in the diameter of the pillar.

Further, FIG. 7 to FIG. 9 illustrate results of a wet development, a dry development, and the development in Example 1 of the treatment sequence (hereinafter, referred to as a weak acid development), respectively. In the wet development, an ordinary developing solution was used and the developing time was 27 seconds. In the dry development, hydrogen bromide was used under a reduced pressure atmosphere (about 500 mTorr) and the developing time was 40 seconds. In the weak acid development, the developing time (specifically, time of supplying the gas of the weak acid) was 120 seconds. Further, after the PEB treatment and before the development, an additional PEB treatment was performed in the dry development, whereas no additional PEB treatment was performed in the wet development and the weak acid development.

As illustrated in FIG. 7, the occurrence rate of defects in the weak acid development was lower than that in the wet development and equal to that in the dry development.

Further, as illustrated in FIG. 8, the exposure sensitivity in the weak acid development was equal to that in the dry development.

Further, as illustrated in FIG. 9, the LCDU being an index of the surface roughness in the weak acid development was lower than those in the wet development and the dry development.

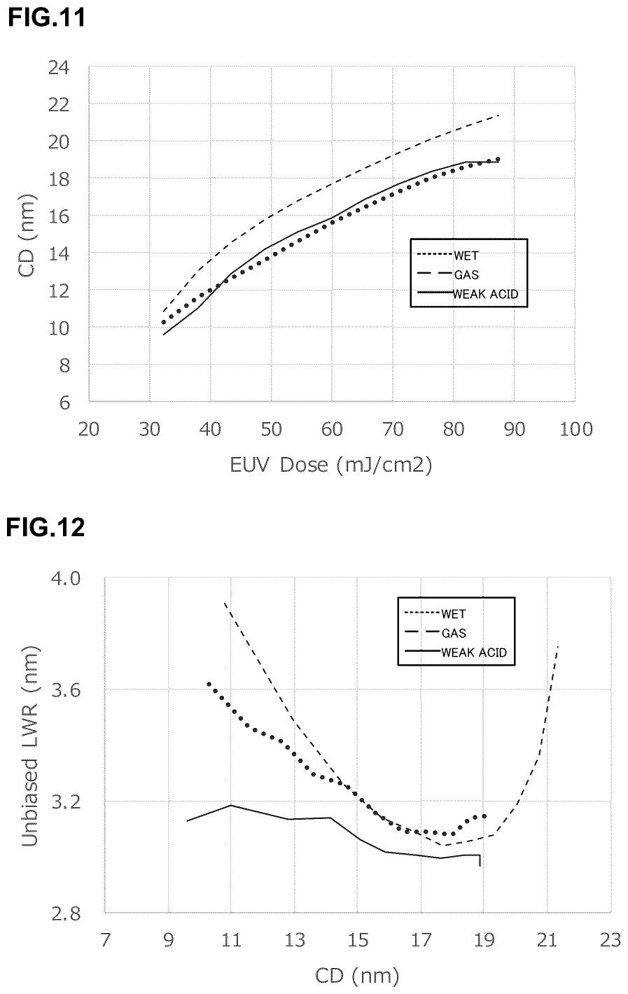

FIG. 10 to FIG. 12 are charts illustrating results at the time of performing the development for forming a line-and-space pattern of the metal-containing resist, FIG. 10 illustrates a relation between a CD, namely, a width of a line and an occurrence rate of defects, FIG. 11 illustrates a relation between an exposure amount and the CD, namely, an exposure sensitivity, and FIG. 12 illustrates a relation between the CD and a uLWR (unbiased Line Edge Roughness). Note that the defects whose occurrence rate is illustrated in FIG. 10 is caused by pattern collapse or chipping of an upper portion of a pattern.

Further, FIG. 10 to FIG. 12 illustrate results of a wet development, a dry development, and the development in Example 1 of the treatment sequence (hereinafter, referred to as a weak acid development), respectively. The wet development and the dry development here are the same as those in the case of the hole pattern. The weak acid development here is different from that in the case of the hole pattern, and the developing time (specifically, time of supplying the gas of the weak acid) was 120 seconds.

As illustrated in FIG. 10 to FIG. 12, the results of the developments for forming the line-and-space pattern were the same as the development results for forming the pillar pattern.

From these results, it is found that the hole pattern and the line-and-space pattern of the metal-containing resist with small surface roughness and few defects can be formed with a suitable exposure sensitivity by the weak acid development.

Note that one conceivable reason why a longer time is required for the weak acid development in the case of the hole pattern than in the line-and-space pattern is the following. Specifically, when the metal-containing resist at the unexposed portion is lowered in molecular weight by the reaction with the gas of the weak acid (specifically, an acid-base), a by-product (gas) is generated. This by-product reacts with the gas of the weak acid and therefore hinders the reaction between the metal-containing resist at the unexposed portion and the gas of the weak acid, namely, development. The hole pattern has more unexposed portions than the line-and-space pattern and is thus larger also in amount of by-product generated. Therefore, the reaction between the metal-containing resist at the unexposed portion and the gas of the weak acid, namely, development is greatly inhibited by the by-product. This is the one conceivable reason why the weak acid development needs a long time in the case of the hole pattern.

Further, the present inventors have confirmed that in the case of not performing the additional PEB treatment, a pattern in a rectangular shape in cross-sectional view can be obtained in the weak acid development.

### Etching Using a Pattern of the Metal-Containing Resist as a Mask

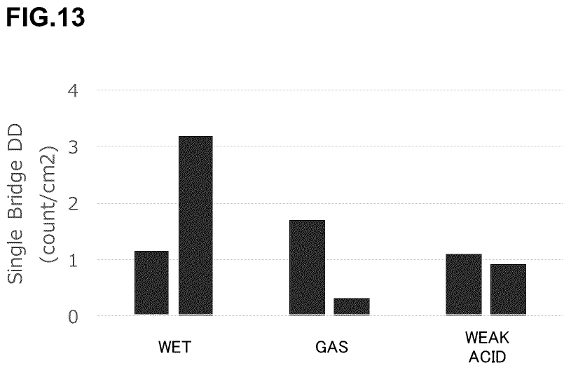

FIG. 13 is a chart illustrating the results of etching using the line-and-space pattern of the metal-containing resist as a mask, and illustrating the occurrence rates of defects (specifically, a bridge defect) in the case of performing the wet development, the dry development, and the weak acid development. The treatment conditions of the wet development, the dry development, and the weak acid development are the same as those when the results in FIG. 10 to FIG. 12 are obtained.

As illustrated in FIG. 13, the occurrence rate of defects in the etching after the development in the weak acid development was lower than that in the wet development and equal to that in the dry development.

### Example 2 of the Treatment Sequence

This example is different in the development process at Step S7 from Example 1 of the treatment sequence. In Example 1 of the treatment sequence, the process of exposing to the acid atmosphere while heating at Step S7b and the process of replacing to the inert gas atmosphere at Step S7c are each performed once. On the other hand, in this example, the process of exposing to the acid atmosphere while heating at Step S7b is performed a plurality of times with the process of replacing to the inert gas atmosphere at Step S7c interposed in between in the development process.

According to this, the replace process at Step S7c removes the above by-product located near above the unexposed portion in the process at Step S7b immediately before it, so that it is possible to suppress the inhibition of the development by the by-product at Step S7b immediately after it, thereby enabling the development to proceed appropriately. Therefore, it is possible to make the development sufficiently proceed in a developing time that is a relatively short time.

This example is preferable particularly when performing development for forming the hole pattern.

### Example 3 of the Treatment Sequence

This example is different in the development process at Step S7 from that in Example 1 of the treatment sequence. In this example, the wet development, namely, the development with the developing solution is performed by the developing unit 200 so as to leave a part of a removal target portion by the development in the metal-containing resist film, before Step S7a to Step S7d in the development process.

In the case of using the developing solution, the development proceeds at a higher speed than in the case of using the gas of the weak acid. Therefore, according to this example, it is possible to reduce the time required for the development.

### Modifications

According to the treatment sequence performed by the wafer treatment system 1, the components of the wafer treatment system 1 may be appropriately omitted. In other words, when the wafer treatment system 1 performs only part of the example of the above treatment sequence, the components of the wafer treatment system 1 which are not used in that treatment sequence to be performed may be omitted.

The acid atmosphere contains both the weak acid component (specifically, the gas of the weak acid) and the organic solvent component (specifically, the gas of the organic solvent) in the above example, but does not need to contain the organic solvent component as long as the acid atmosphere contains the weak acid component.

The acid atmosphere contains the gas of the weak acid as the weak acid component in the above example, but may contain mist of the weak acid instead of the gas of the weak acid.

Besides, the acid atmosphere may contain both the gas and mist of the weak acid as the weak acid component.

However, the acid atmosphere preferably contains the gas of the weak acid without containing the mist of the weak acid, as the weak acid component. This is because the uniformity of the development result within the wafer W is higher.

The acid atmosphere may contain mist of the organic solvent instead of the gas of the organic solvent, as the organic solvent component.

Besides, the acid atmosphere may contain both the gas and the mist of the organic solvent as the organic solvent component.

However, the acid atmosphere preferably contains the gas of the organic solvent without containing the mist of the organic solvent as the organic solvent component. This is because the uniformity of the development result within the wafer W is higher.

A structure for forming a flow of the inert gas toward the peripheral edge along the rear surface of the wafer W may be provided in the developing unit 200 in order to prevent the gas of the weak acid or the like from going around to the rear surface of the wafer W.

After the weak acid development and before the etching using the pattern obtained by the weak acid development as a mask, plasma processing may be performed on the wafer W. This plasma processing is performed, for example, in the etching apparatus which performs the above etching.

The embodiments disclosed herein are examples in all respects and should not be considered to be restrictive. Various omissions, substitutions, and changes may be made in the embodiments without departing from the scope and the spirit of the attached claims. For example, configuration requirements of the above embodiments can be arbitrarily combined. From the arbitrary combination, the operations and effects about the configuration requirements relating to the combination can be obtained as a matter of course, and other operations and other effects apparent to those skilled in the art are obtained from the description herein.

Besides, the effects explained herein are merely explanatory or illustrative in all respects and not restrictive. In other words, the technique relating to this disclosure can offer other effects apparent to those skilled in the art from the description herein in addition to or in place of the above effects.

Note that the following configuration examples also belong to the technical scope of this disclosure.
(1) A substrate treatment method including
   developing a substrate on which a coating film of a metal-containing resist has been formed and which has been subjected to exposure processing and a heat treatment after the exposure processing, wherein
   the developing includes exposing the substrate to an acid atmosphere being an atmosphere containing at least any one of gas and mist of a weak acid, while heating the substrate.
(2) The substrate treatment method according to the (1), wherein
   the weak acid has an acid strength at which development of the metal-containing resist does not proceed at room temperature.
(3) The substrate treatment method according to the (1) or (2), wherein
   the developing performs the exposing while heating a plurality of times, with replacing an atmosphere around the substrate from the acid atmosphere to an atmosphere of an inert gas interposed in between.
(4) A substrate treatment apparatus for treating a substrate, the substrate treatment apparatus including:
   a developing unit configured to develop the substrate; and
   a controller, wherein:
   the developing unit has:
      a chamber configured to house the substrate;
      a hot plate configured to heat the substrate in the chamber; and
      a gas discharger configured to discharge at least any one of gas and mist of a weak acid into the chamber;
   the controller controls the substrate treatment apparatus to execute developing the substrate on which a coating film of a metal-containing resist has been formed and which has been subjected to exposure processing and a heat treatment after the exposure processing; and
   the developing includes exposing the substrate which has been subjected the heat treatment after the exposure processing, to an acid atmosphere being an atmosphere containing at least any one of the gas and the mist of the weak acid, while heating the substrate.
(5) The substrate treatment apparatus according to the (4), wherein
   the weak acid has an acid strength at which development of the metal-containing resist does not proceed at room temperature.
(6) The substrate treatment apparatus according to the (4) or (5), wherein:
   the developing unit further includes another gas discharger configured to discharge an inert gas into the chamber; and
   the developing performs the exposing while heating a plurality of times, with replacing an atmosphere around the substrate from the acid atmosphere to an atmosphere of an inert gas interposed in between.
(7) A computer-readable storage medium storing a program running on a computer of a controller controlling a substrate treatment apparatus so as to cause the substrate treatment apparatus to execute a substrate treatment method,
   the substrate treatment method including developing a substrate on which a coating film of a metal-containing resist has been formed and which has been subjected to exposure processing and a heat treatment after the exposure processing, wherein
   the developing includes exposing the substrate to an acid atmosphere being an atmosphere containing at least any one of gas and mist of a weak acid, while heating the substrate.

According to this disclosure, it is possible to obtain an excellent pattern of a metal-containing resist.

What is claimed is:

1. A substrate treatment method comprising
developing a substrate on which a coating film of a metal-containing resist has been formed and which has been subjected to exposure processing and a heat treatment after the exposure processing, wherein
the developing comprises exposing the substrate to an acid atmosphere being an atmosphere containing at least any one of gas and mist of a weak acid, while heating the substrate.

2. The substrate treatment method according to claim 1, wherein
the weak acid has an acid strength at which development of the metal-containing resist does not proceed at room temperature.

3. The substrate treatment method according to claim 1, wherein
the developing performs the exposing while heating a plurality of times, with replacing an atmosphere around the substrate from the acid atmosphere to an atmosphere of an inert gas interposed in between.

4. A substrate treatment apparatus for treating a substrate, the substrate treatment apparatus comprising:
a developing unit configured to develop the substrate; and
a controller, wherein:
the developing unit has:
a chamber configured to house the substrate;
a hot plate configured to heat the substrate in the chamber; and
a gas discharger configured to discharge at least any one of gas and mist of a weak acid into the chamber;
the controller controls the substrate treatment apparatus to execute developing the substrate on which a coating film of a metal-containing resist has been formed and which has been subjected to exposure processing and a heat treatment after the exposure processing; and
the developing comprises exposing the substrate which has been subjected the heat treatment after the exposure processing, to an acid atmosphere being an atmosphere containing at least any one of the gas and the mist of the weak acid, while heating the substrate.

5. The substrate treatment apparatus according to claim 4, wherein
the weak acid has an acid strength at which development of the metal-containing resist does not proceed at room temperature.

6. The substrate treatment apparatus according to claim 4, wherein:
the developing unit further comprises another gas discharger configured to discharge an inert gas into the chamber; and
the developing performs the exposing while heating a plurality of times, with replacing an atmosphere around the substrate from the acid atmosphere to an atmosphere of an inert gas interposed in between.

7. A computer-readable storage medium storing a program running on a computer of a controller controlling a substrate treatment apparatus so as to cause the substrate treatment apparatus to execute a substrate treatment method,
the substrate treatment method comprising developing a substrate on which a coating film of a metal-containing resist has been formed and which has been subjected to exposure processing and a heat treatment after the exposure processing, wherein
the developing comprises exposing the substrate to an acid atmosphere being an atmosphere containing at least any one of gas and mist of a weak acid, while heating the substrate.
